(19) United States
(12) Patent Application Publication
(10) Pub. No.: US 2012/0067521 A1
(43) Pub. Date: Mar. 22, 2012

(54) VACUUM PROCESSING SYSTEM

(75) Inventors: Takahiro SHIMOMURA, Kudamatsu (JP); Yutaka Kudou, Kudamatsu (JP); Takashi Uemura, Kudamatsu (JP); Masakazu Isozaki, Shunan (JP)

(73) Assignee: Hitachi High-Technologies Corporation

(21) Appl. No.: 12/968,357

(22) Filed: Dec. 15, 2010

(30) Foreign Application Priority Data
Sep. 21, 2010 (JP) 2010-210355

(51) Int. Cl. H01L 21/3065; C23C 16/458

(52) U.S. Cl. 156/345.31; 118/719

(57) ABSTRACT

A vacuum processing system including a cassette holder for setting up cassettes in which samples are stored, an air-transfer chamber for transferring the samples, lock chambers for storing the samples transferred from the air-transfer chamber, the lock chambers being capable of switching between air atmosphere and vacuum atmosphere in their inside, a vacuum transfer chamber connected to the lock chambers, vacuum containers for processing the samples transferred via the vacuum transfer chamber, a cooling chamber for cooling the samples down to a first temperature, the samples being processed in at least one of the vacuum containers, and a cooling unit for cooling the samples down to a second temperature, the samples being cooled in the cooling chamber. The cooling unit is deployed in the air transfer chamber, and has a cooling part for cooling the samples, being cooled in the cooling chamber, down to the second temperature.

### BACKGROUND OF THE INVENTION

The present invention relates to the configuration of a vacuum processing system which is equipped with a transfer mechanism for transferring a substrate to be processed (which, hereinafter, will be simply referred to as “wafer”, including such members as a wafer and a substrate-shaped sample) among such chambers as vacuum containers, a cooling chamber, and a vacuum transfer chamber. More particularly, the present invention relates to the configuration of the vacuum processing system where the high-temperature wafer that has been processed inside the vacuum containers is cooled through the use of the cooling chamber.

In semiconductor-device fabrication steps, there exist steps at which high-temperature processings are necessary, such as a film formation step and an ashing step. In these steps, it is required to transfer the wafer that has been processed at a high temperature (: about 100° C. to 800° C.). This wafer processed at the high temperature results in occurrence of the following problems: Namely, the concentration of a thermal stress due to the steep temperature change gives rise to the occurrence of a scratch onto the wafer's edge surface or rear surface. Then, the occurrence of this scratch results in the occurrence of a wafer cracking. Otherwise, a wafer-storing cassette is heated excessively by the heat brought by the wafer. As a result, an organic degas is generated from the cassette. Then, this organic degas adheres to the wafer, or, in an extreme case, gives rise to the occurrence of a thermal deformation of the cassette.

Also, the wafer after being processed is stored into a slot, i.e., a storage unit of the same cassette as the one for a wafer before being processed. Here, a high-reactivity gas is released from the surface of the after-processed wafer stored into the slot, depending on the temperature of the after-processed wafer, and adhering matters to the wafer. Moreover, this released gas adheres to the before-processed wafer stored inside the same cassette. In this way, this released gas adheres to the surface or rear surface of the before-processed wafer as microscopic foreign matters generated by the reactions such as surface reaction and vapor-phase reaction. Namely, this adhesion of the gas gives rise to a problem of the occurrence of foreign matters and pattern defects. Also, if the gas is composed of a contaminating substance, even the gas-level adhesion, in some cases, becomes a cause for giving rise to occurrence of an electrical lowering in the yield. This has become another problem. In order to solve these problems, JP-A-2002-280370 has disclosed that the degas processing and the cooling processing are executed such that plural pieces of high-temperature-processed wafers are transferred into the inside of a cooling mechanism while the wafers are being mounted on a transfer robot capable of supporting the plural pieces of wafers. Also, JP-A-2007-95856 has disclosed that the adhesion of the foreign matters onto the before-processed wafer is suppressed by storing the before-processed wafer and the after-processed wafer in a manner of being distributed into different cassettes. Also, JP-A-2009-88437 (corresponding to U.S. Patent Publication No. 2009/092468) has disclosed that the adhesion of the foreign matters and formation of a natural oxide film are prevented by executing the gas replacement such that an inert gas is purged over the after-processed wafer from a gas injection pipe provided at an inlet/outlet into/from the cassette. No disclosure, however, has been made concerning the cooling of the after-processed wafer. Also, JP-A-11-102951 has disclosed that, through the use of two steps, i.e., the cooling in the vacuum inside an auxiliary vacuum chamber and the cooling in the air, the high-temperature wafer is cooled down to a temperature at which the closed-type cassette undergoes no thermal deformation. No disclosure, however, has been made regarding a configuration that the in-vacuum cooling and the in-air cooling are executed in different units with each other.

### SUMMARY OF THE INVENTION

However, in a vacuum processing device including the vacuum containers, when applying the above-described prior art on the vacuum side thereby to cool the high-temperature wafer down to the temperature at which the cassette undergoes no thermal deformation, and when returning the cooled wafer back to the cassette, a time is necessitated for this cooling. This drawback delays the transfer of the pre-processed wafer, thereby lowering a processing efficiency of the vacuum processing device. Also, in recent years, because of even further microminiaturization of the semiconductor devices, the requested values for foreign matters and metal contamination with respect to the semiconductor devices have also become even severer. Concretely, the reduction of 50-nm-or-less microscopic foreign matters has become absolutely necessary already. Simultaneously, the reduction, suppression, and avoidance of the adhesion of the microscopic foreign matters and the gas contamination onto the before-processed/after-processed wafers are also becoming more and more important.

The present invention has been devised in view of these problems. Accordingly, an object of the present invention is to provide the following vacuum processing system: Namely, this vacuum processing system allows a wafer to be cooled with a high efficiency down to a temperature at which the microscopic foreign matters and gas contamination present no problem. Here, this wafer has been processed at the high temperature in the vacuum containers.

In the present invention, there is provided a vacuum processing system including a cassette holder for setting up cassettes in which a plurality of samples are stored, an air transfer chamber for transferring the samples, lock chambers for storing the samples transferred from the air transfer chamber, the lock chambers being capable of making a switching between air atmosphere and vacuum atmosphere in their inside, a vacuum transfer chamber connected to the lock chambers, vacuum containers for processing the samples transferred via the vacuum transfer chamber, a cooling chamber for cooling the samples down to a first temperature, the samples being processed in at least one of the vacuum containers, and a cooling unit for cooling the samples down to a second temperature, the samples being cooled in the cooling chamber, wherein the cooling unit is deployed in the air transfer chamber, the cooling unit having a cooling part for cooling the samples down to the second temperature, the samples being cooled in the cooling chamber.

According to the configuration of the present invention applied, it becomes possible to cool, with a high efficiency, a wafer which has been processed at the high temperature in the vacuum containers.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for illustrating the configuration of a vacuum processing system of the present invention;

FIG. 2 is a cross-sectional diagram of a cooling station 6 acquired when seen from its side surface;

FIG. 3 is a cross-sectional diagram of the cooling station 6 acquired when seen from its front surface;

FIG. 4 is an explanatory diagram for explaining the configuration of a stage 15;

FIG. 5 is an explanatory diagram for explaining the set-up locations of purge members 11;

FIG. 6 is an explanatory diagram for explaining the profile of the purge members 11;

FIG. 7 is a diagram for illustrating the correlation relationship between the temperature of a wafer 8 and the cooling time of the wafer 8; and

FIG. 8 is a diagram for illustrating the concentration measurement on a released gas from the surface of the wafer 8.

### DESCRIPTION OF THE INVENTION

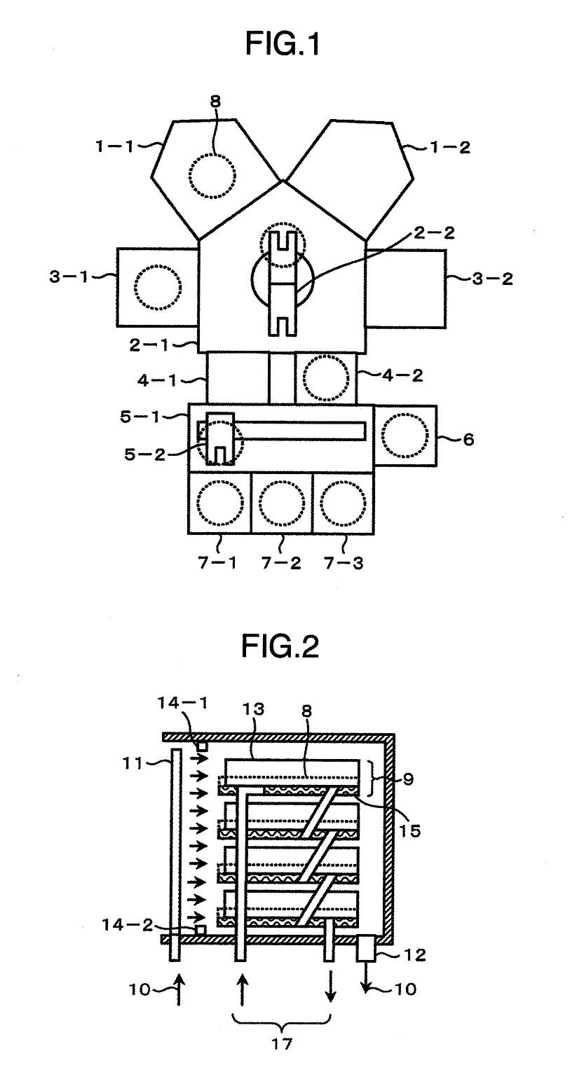

Hereinafter, referring to FIG. 1 to FIG. 8, the explanation will be given below concerning an embodiment of the present invention.

FIG. 1 is a diagram for illustrating the configuration of a vacuum processing system of the present invention. Incidentally, here, the explanation will be given regarding the present embodiment, selecting an example where an ashing processing is executed in vacuum containers.

The vacuum processing system includes a plurality of ashing units 1 for executing the ashing processing, a vacuum transfer chamber 2-1 equipped with a first transfer robot 2-2 for executing the transfer of a wafer 8 in vacuum to the ashing units 1, cooling units 3, i.e., first cooling mechanisms connected to the vacuum transfer chamber 2-1, lock chambers 4 capable of making a switching between an air atmosphere and the vacuum atmosphere in order to execute the transfer of the wafer 8 into/from the lock chambers 4, an air transfer unit 5-1 equipped with a second transfer robot 5-2 for executing the transfer of the wafer 8 into/from the lock chambers 4, a cooling station 6, i.e., a second cooling mechanism connected to the air transfer unit 5-1, and cassettes 7 into which the wafers 8 are stored in the air transfer unit 5-1.

In the ashing unit 1, the wafer 8 is subjected to the ashing processing at a high temperature of about 300° C. Next, the ashing-processing-subjected wafer 8 is transferred to the cooling unit 3, i.e., the first cooling mechanism, by the first transfer robot 2-2. In the cooling unit 3, the wafer 8 is cooled down to about 100° C. Here, about 100° C. refers to a range of 90° C. to 110° C. Also, as described above, the cooling temperature in the cooling unit 3 has been set at about 100° C. This setting is executed in order to suppress a situation that the moisture in the air adheres to the surface of the wafer 8 when the wafer 8 is exposed onto the air. Simultaneously, this setting is executed in order to avoid a situation that the ashing-processing efficiency in the ashing unit 1 becomes lowered. This latter situation occurs, because a time needed for cooling the wafer 8, which is heated at about 300° C., down to the temperature at which the wafer 8 can be returned to the cassette 7 turns out to be a significantly long time. Moreover, the wafer 8, which is now cooled down to about 100° C., is transferred from the cooling unit 3 to the lock chamber 4 by the first transfer robot 2-2. Then, after being purged into the air atmosphere in the lock chamber 4, the wafer 8 is transferred to the cooling station 6 by the second transfer robot 5-2.

A plurality of slots 9 for storing and cooling the transferred wafer 8 is provided inside the cooling station 6. Within each slot 9, there is provided each stage 15 which can be maintained at a predetermined temperature by circulating a cooling medium theretrough. The wafer 8, which is transferred to the cooling station 6 by the second transfer robot 5-2, is stored into a slot 9 in which none of the wafers 8 is stored. Then, the wafer 8 is cooled down to 30° C. or room temperature (: 25° C.) by bringing the wafer 8 into a 10-second to 70-second-time-interval proximity-holding state on the stage 15 corresponding to this slot 9. Incidentally, 30° C. or room temperature (: 25° C.), i.e., the cooling temperature, is a temperature which is substantially equal to that of a before-processed wafer 8 stored in a cassette 7. Namely, this temperature is set in order to allow the environment of the cassette 7 to always remain the same as the environment of an unprocessed cassette 7 even in a case where the before-processed wafer 8 and the after-processed wafer are mixed within the cassette 7. Also, the proximity holding is a state where a spacing is provided between the rear surface of the wafer 8 and the stage 15 so that they are not brought into contact with each other. In the present embodiment, the proximity holding has been implemented by setting up vacuum adhesion pads 18. The execution of the proximity holding makes it possible to suppress the occurrence of a scratch onto the edge surface or rear surface of the wafer 8, thereby allowing the suppression of a cracking of the wafer 8. Also, it becomes possible to prevent the adhesion of the foreign matters and the contamination onto the edge surface or rear surface of the wafer 8.

Purge members 11 are provided on the side of a transfer inlet/outlet of the wafer 8 into/from the cooling station 6, i.e., the second cooling mechanism. Simultaneously with the starting of the cooling processing in the cooling station 6, a clean dry air 10 is purged into each slot 9 from the purge members 11. Then, the clean dry air 10 is exhausted to an exhaust outlet 12. Here, the exhaust outlet 12 is provided on the opposite side to the purge members 11, and at a back lower portion of the cooling station 6. The cooling-processing starting point-in-time refers to a point-in-time when a lot processing is started. The cooling-processing starting point-in-time, however, is not limited to the lot-processing starting point-in-time. Namely, it may be a point-in-time when the wafer 8 is transferred into the stage 15, or a point-in-time when the wafer 8 whose ashing processing has been terminated is transferred into the lock chamber 4. Also, the lot processing means the execution of the processing for all of the wafers 8 stored into at least one cassette 7, or of the processing for the wafers 8 whose number-of-pieces to be processed is specified in advance.

After that, the wafer 8, which has been cooled down to 30° C. or room temperature (: 25° C.), is taken out of the cooling station 6 by the second transfer robot 5-2 inside the air transfer unit 5-1. Moreover, the wafer 8 is stored into the cassette 7, which terminates the processing for the wafer 8. Furthermore, the above-described processing is repeated until all of the ashing processings have been terminated with respect to all of the wafers 8 stored in advance into the cassettes 7. In the vacuum processing system as described above, the execution of the two-step cleanings on the vacuum side and on the air side makes it possible to suppress the concentration of the thermal stress due to the steep temperature change without lowering the ashing-processing efficiency in the ashing unit 1. Also, the execution of the two-step cleanings makes it possible to prevent the contamination due to the degas generated from the cassettes 7 by the heat brought from the wafers 8, and the thermal deformation of the cassettes 7 caused by the heat brought from the wafers 8. This feature allows implementation of the compatibility between the efficient ashing processing and the efficient cooling processing.

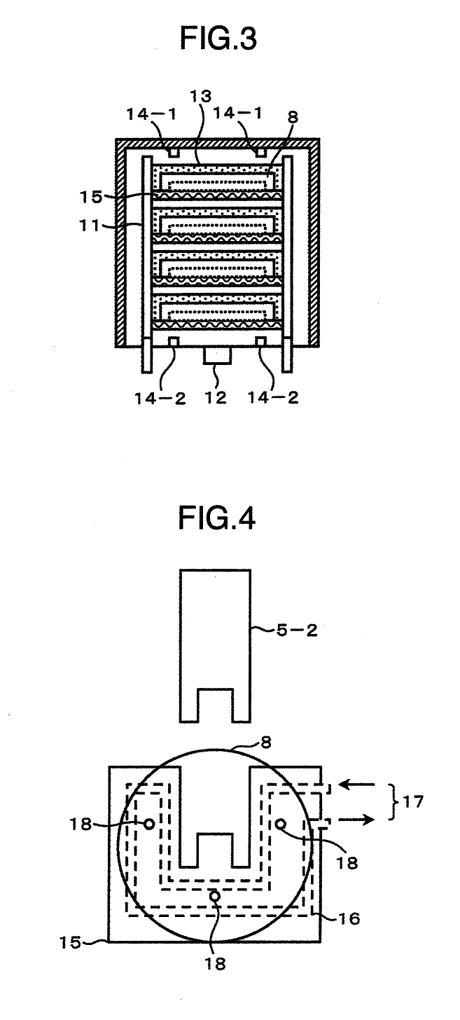

Hereinafter, referring to FIG. 2 and FIG. 3, the explanation will be given below regarding the configuration of the cooling station 6. FIG. 2 is a cross-sectional diagram of the cooling station 6 acquired when seen from its side surface. FIG. 3 is a cross-sectional diagram of the cooling station 6 acquired when seen from its front surface. The cooling station 6 includes each slot 9 under which there is provided each stage 15 for cooling the wafer 8 processed at the high temperature, the purge members 11 for injecting the clean dry air 10 for eliminating the high-reactivity gas released from the surface of the wafer 8, and preventing the high-reactivity gas from flowing into the air transfer unit 5-1 and the cassettes 7, and the exhaust outlet 12 for exhausting the clean dry air 10 injected from the purge members 11. Incidentally, in addition to the clean dry air 10, an inert gas such as nitrogen gas, argon gas, or helium gas may also be injected.

The number of the slots 9 set up inside the cooling station 6 is set at a number which is greater than or equal to the number of the ashing units 1. Namely, the number of the slots 9 has become the number which does not permit the lowering of the ashing-processing efficiency and the lowering of the cooling-processing efficiency of the cooling units 3, i.e., the first cooling mechanisms. Also, it is made possible that each slot is allocated to whatever of the ashing units 1, and that this allocation relationship is fixed. As a consequence, it is made possible that the wafer, which has been subjected to the ashing processing and has been contaminated in an ashing unit 1, will not be stored into the slots except the slot which had been allocated to this ashing unit 1 in advance. This feature has allowed implementation of prevention of the cross contamination (i.e., mutual pollution). In the present embodiment, the four units of slots 9 are employed with respect to the two units of ashing units 1. Also, the cooling station 6 is configured such that the slots 9 are multilayered in the longitudinal direction.

Incidentally, the respective slots 9 are partitioned for each slot 9 by covers 13. Each of these covers 13 is configured such that an aperture is provided on its front-surface side into which a wafer 8 is transferred. This configuration is designed so that the clean dry air 10 purged into each slot 9 from the purge members 11 does not remain inside each slot 9. The employment of a configuration like this spatially isolates a certain slot 9 from the other wafers 8 stored in the other slots 9. On account of this isolation configuration, the injection of the clean dry air 10 or the inert gas such as nitrogen gas, argon gas, or helium gas allows the gas component released from the surface of the wafer 8 to be exhausted to the outside of the air transfer unit 5-1 so that the gas component does not adhere to the other wafers 8. Also, if the passing number-of-times of the wafers 8 increases, the holding position of a wafer 8 relative to the second transfer robot 5-2 of the air transfer unit 5-1 gradually shifts with a lapse of time. As a result, when the wafer 8 is stored into a cassette 7, the wafer 8 comes into contact with the transfer inlet/outlet of the wafer 8 into/from the cassette 7, or a wafer already stored inside the cassette 7. This contact brings about occurrence of the following possibility: Namely, this contact gives rise to the occurrence of foreign matters, thus causing the foreign matters to adhere to the wafer 8. Moreover, a cracking or chipping of the wafer 8 occurs in an extreme case. In view of this possibility, there are provided sensors for making a judgment as to whether or not the wafer 8 can be safely stored into the cassette 7. Here, this judgment is made by detecting the position of the wafer 8 immediately after the wafer 8 is taken out of the cooling station 6 by the second transfer robot 5-2. Also, these sensors are provided as follows:

As illustrated in FIG. 2 and FIG. 3, in order to monitor the position of the wafer 8, at the transfer inlet/outlet of the wafer 8 into/from the cooling station 6, two units of light-projecting sensors 14-1 are provided at the right and left positions on the upper side, and two units of light-receiving sensors 14-2 are provided at the right and left positions on the lower side. The position of the wafer 8 is detected and monitored in such a manner that the light-receiving sensors 14-2 are light-shielded. This monitoring makes it possible to prevent an abnormality such as the cracking of the wafer 8. Also, if the position shift of the wafer 8 has occurred at the time of the transfer of the wafer 8 into/from the cooling station 6, the cooling processing can be halted immediately. This immediate halting makes it possible to avoid and prevent the cracking of the wafer 8 and the contact of the wafer 8 with the cassette 7 or the like. Also, if the position shift of the wafer 8 has occurred at the time of the transfer of the wafer 8 into/from the cooling station 6, this position shift can be addressed by correcting the operation of the second transfer robot 5-2 for storing the wafer 8, or by correcting the position shift using an (not-illustrated) alignment mechanism.

Next, referring to FIG. 4, the explanation will be given below concerning the stage 15, on which the wafer 8 is mounted by the proximity holding, and which cools the wafer 8.

The stage 15 is cut out into the same profile as the profile of a (not-illustrated) holding unit for holding the wafer 8. Here, this holding unit is included in the second transfer robot 5-2 set up inside the air transfer unit 5-1. Moreover, a cooling-water flowing channel 16 for cooling the wafer 8 is formed inside the stage 15 as is illustrated in FIG. 4. The wafer 8 is cooled down to a predetermined temperature by circulating a cooling water 17, e.g., water at room temperature, through the cooling-water flowing channel 16. Incidentally, a cooling medium whose temperature is adjusted by a (not-illustrated) temperature adjuster is employable as the cooling medium to be circulated through the cooling-water flowing channel 16. When the cooling medium of the temperature adjuster is employed, its temperature can be set arbitrarily. This condition allows implementation of the higher-speed cooling as compared with the cooling where the room-temperature water is employed.

Also, as the cooling time of the wafer on the stage 15, an arbitrary time can be input as the recipe (i.e., cooling-processing condition) parameter for the cooling processing by the cooling station 6. As described above, the profile of the stage 15 is formed into the same profile as the profile of the holding unit of the second transfer robot 5-2 for holding the wafer 8. This feature makes it possible to exclude the pressure-mechanism-based passing operation of the wafer 8 which has been frequently employed from conventionally. As a consequence, it becomes possible to implement the direct passing of the wafer 8 from the second transfer robot 5-2 to the stage 15. This feature also allows implementation of a cost reduction and a throughput enhancement in the vacuum processing system.

Also, in the prior arts, the shift of the wafer 8, which is caused to occur when the wafer 8 is mounted onto the stage 15, has been avoided by providing a holding unit such as a guide. In recent years, however, the following problem has appeared: Namely, the outer circumferential portion of the wafer 8 comes into contact with the holding unit such as a guide. Then, this contact gives rise to the generation of foreign matters from the outer circumferential portion of the wafer 8. Accordingly, in the present embodiment, the stage structure is employed where the holding unit such as a guide for holding the wafer 8 is excluded. This stage structure is of course employed in order to reduce the contact between the outer circumferential portion of the wafer 8 and the holding unit for holding the wafer 8.

On account of this employment of the stage structure, in some cases, the wafer 8 transferred into the stage 15 shifts from predetermined mounting positions of the wafer 8. This shift is caused to occur if the set amount of the clean dry air 10 injected from the purge members 11 is insufficient in its adjustment. In order to prevent the occurrence of this shift of the wafer 8, the vacuum adhesion pads 18 for achieving the vacuum adhesion of the wafer 8 are set up at the predetermined mounting positions of the wafer 8 on the surface of the stage 15.

The vacuum adhesion pads 18 are composed of a resin-based material such as, e.g., fluorine rubber, Teflon (: registered trademark), and polyimide resin. As illustrated in FIG. 4, the vacuum adhesion pads 18 are set up at a 0.5-mm height and at the three mounting positions of the wafer 8 on the stage 15. The above-described vacuum adhesion using the vacuum adhesion pads 18 makes it possible to prevent the shift of the wafer 8, even if no consideration is given to the influence of the flow amount of the clean dry air 10 injected from the purge members 11. Also, the above-described vacuum adhesion allows implementation of a tremendous reduction in the contact area between the rear surface of the wafer 8 and the stage 15. This feature makes it possible to prevent the adhesion of the foreign matters and the contamination onto the rear surface of the wafer 8. Also, the above-described vacuum adhesion is designed into a structure where a manual operation allows the switching between the adhesion's ON and OFF.

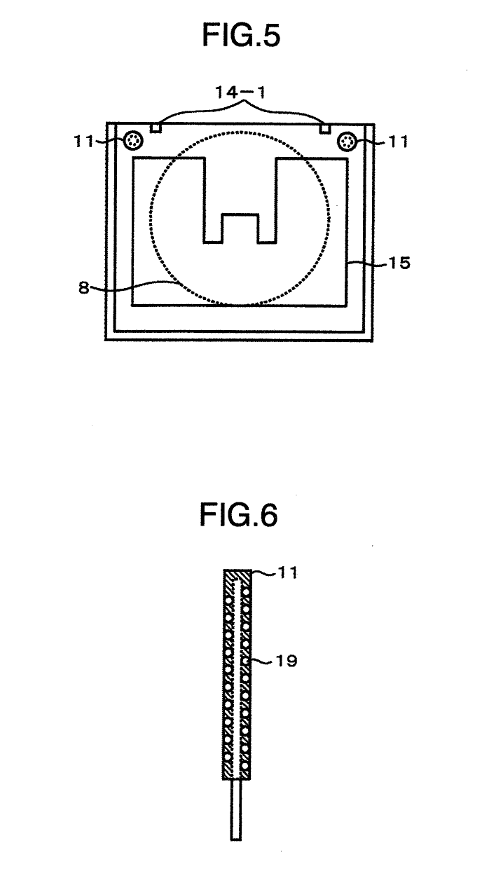

Next, referring to FIG. 5 and FIG. 6, the explanation will be given below concerning the set-up locations of the purge members 11 and the profile of the purge members 11, respectively.

As illustrated in FIG. 5, the purge members 11 are set up at the right and left of the transfer inlet/outlet of the wafer 8 into/from the cooling station 6, and at the positions at which the purge members 11 do not interfere with the transfer-in/out operation of the wafer 8 by the second transfer robot 5-2. Also, the purge members 11 are set up such that the purge members 11 are perpendicular to the slots 9.

Next, the explanation will be given below regarding the profile of the purge members 11. The purge members 11 are of a hollow cylindrical profile, and are equal to the height of the four-stage slots 9 in length. When the vertical direction is defined as the longitudinal direction, injection outlets 19 for injecting the clean dry air 10 or the inert gas such as nitrogen gas, argon gas, or helium gas are provided uniformly in the longitudinal direction and in the circumferential direction, respectively. The arrangement of the injection outlets 19, however, is not limited to the arrangement described above. Namely, in the longitudinal direction, the injection outlets 19 may be set up in proximity to the positions opposed to the stages 15. Meanwhile, in the circumferential direction, the injection outlets 19 may be set up at the positions facing the slots 9. Also, the height of the slots 9 is not specifically limited to the height of the four-stage slots 9, but is a height which is equivalent to the number-of-stages of the slots 9. Also, the number-of-stages of the slots 9 is equal to or larger than the number of the vacuum containers (i.e., the ashing units 1 in the present embodiment).

The clean dry air 10 or the inert gas such as nitrogen gas, argon gas, or helium gas is purged toward each slot 9 from the injection outlets 19. Then, the clean dry air 10 or the inert gas is pushed out to the exhaust outlet 12 without permitting the gas released from the wafer 8 to remain inside each slot 9. Here, the exhaust outlet 12 is provided on the opposite side to the transfer inlet/outlet of the wafer 8 into/from the cooling station 6, and on the bottom surface of the cooling station 6. This purging mechanism allows implementation of the exclusion of the gas which has adhered to the surface of the wafer 8. Accordingly, it becomes possible to avoid and prevent the situation that the released gas from the wafer 8 flows into the air transfer unit 5-1 or the cassettes 7.

Also, the clean dry air 10 or the inert gas such as nitrogen gas, argon gas, or helium gas is injected from the purge members 11. This injection allows implementation of an enhancement in the cooling effect onzz the wafer 8. Simultaneously, the clean dry air 10 or the inert gas is positively subjected to the exhaust processing from the purge members 11 to the exhaust outlet 12. This positive exhaust processing makes it possible to exclude the degas released from the wafer 8, and to suppress the situation that the degas is back-flown to the air transfer unit 5-1, and the situation that a degas released from a wafer 8 stored inside another slot 9 is flown into the present slot 9 of the cooling station 6 where the present wafer 8 is stored. Consequently, it becomes possible to prevent the influence on the after-cooling-processed wafer 8. Also, the wafer 8 is cooled in the cooling station 6 down to the temperature at which the degas is not released from the wafer 8, then being returned to the cassette 7. This processing makes it possible to suppress the adhesion of the microscopic foreign matters onto a before-ashing-processed wafer 8 which is stored into the same cassette 7 as the one for the present wafer 8.

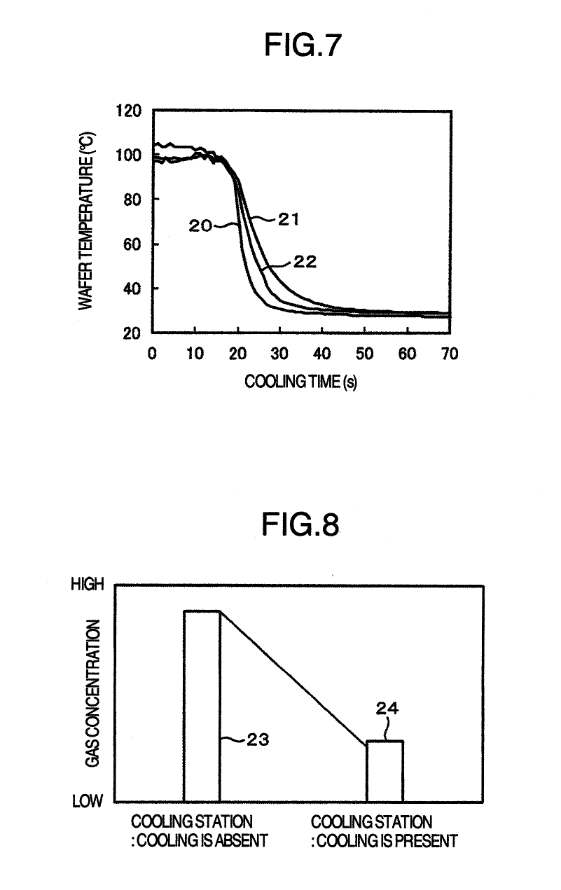

FIG. 7 illustrates a result which is acquired by using the vacuum processing system of the present invention applied, and making an investigation into the correlation relationship between the temperature of the wafer 8 and the cooling time of the wafer 8.

In the ashing unit 1, using the silicon-based wafer 8, a 60-second-time-interval electrical discharge with oxygen gas is carried out at an about 300-° C. ashing stage temperature. After that, in the cooling unit 3, the wafer 8 is cooled down to about 100° C. Moreover, the wafer 8 is transferred onto the stage 15 inside the cooling station 6. Furthermore, with respect to the following three cases, the investigation has been made into the correlation relationship between the temperature of the silicon-based wafer 8 and the cooling time of the silicon-based wafer 8: A case where the wafer 8 is brought into contact with the surface of the stage 15, a case where the wafer 8 is brought into the proximity-holding state by the stage 15, and a case where the clean dry air 10 is purged over the wafer 8 which is held in the proximity-holding state.

The cooling-evaluation conditions in the cooling station 6 have been set as follows: The temperature of the stage 15 is set at 25° C. (: room temperature), and the cooling time of the wafer 8 on the stage 15 is set at 70 seconds. Incidentally, concerning the cooling evaluation in the case where the wafer 8 is brought into contact with the surface of the stage 15, the cooling evaluation is carried out in the state were the vacuum adhesion pads 18 are removed from the stage 15, and where the rear surface of the wafer 8 comes into contact with the entire surface of the stage 15.

As a consequence of the cooling evaluation, as illustrated in FIG. 7, in the case (21) where the wafer 8 is brought into the proximity-holding state, the cooling time becomes longer as compared with the case (20) where the wafer 8 is brought into contact with the stage 15. Also, in the case (22) where the clean dry air 10 is purged over the wafer 8 held in the proximity-holding state, it has been found successful that the cooling time has been improved as compared with the case (21) where the wafer 8 is brought into the proximity-holding state. Namely, it has been found successful that the cooling time has come closer to the result (20) where the wafer 8 is brought into contact with the stage 15. This is because when the clean dry air 10 is purged over the wafer 8 held in the proximity-holding state, the gas released from the surface of the resist-based wafer 8 at the high temperature is exhausted and the wafer is cooled by the clean dry air. Also, it has been confirmed based on a visual check whether or not there has occurred a scratch onto the rear surface of the wafer 8. As a result, it has been confirmed successfully that there has occurred none of the scratch onto the rear surface thereof. Based on this investigation result, it has been demonstrated successfully that the execution of the proximity holding and the purging by the clean dry air 10 in the present embodiment allows implementation of the compatibility between the cooling performance and the suppression of a scratch onto the rear surface of the wafer 8.

Next, the explanation will be given below regarding a result which is acquired by using the above-described ashing unit 1, and measuring the gas concentration of a gas released from the surface of the wafer 8 in dependence with the temperature of the wafer 8.

With respect to the following two cases, the measurement has been made concerning the gas concentration of the gas released from the surface of the resist-based wafer 8 stored into the cassette 7: A case where, using the resist-based wafer 8, the 60-second-time-interval electrical discharge with oxygen gas is carried out at the about 300-° C. ashing stage temperature in the ashing unit 1, and after that, the wafer 8 is cooled down to about 100° C. in the cooling unit 3, and is then stored into the cassette 7; and a case where the resist-based wafer 8 is cooled down to about 100° C. in the cooling unit 3 as described above, and further, the wafer 8 is cooled down to 30° C. or lower by using the cooling station 6, and is then stored into the cassette 7.

Incidentally, in the above-described measurement, the cooling conditions in the cooling station 6 have been set as follows: The temperature of the stage 15 is set at 25° C. (: room temperature), and the proximity holding is established between the wafer 8 and the stage 15, and the cooling time is set at 70 seconds. Then, the clean dry air 10 is purged over the wafer 8 from the purge members 11.

As a consequence of the measurement, as illustrated in FIG. 8, in the case (23) where the resist-based wafer 8 is stored into the cassette 7 as it is, i.e., without using the cooling station 6, the gas concentration released from the surface of the resist-based wafer 8 has been found to be a high-concentration result. In contrast thereto, in the case (24) where the resist-based wafer 8 is cooled sufficiently down to around 30° C. inside the cooling station 6, and is then stored into the cassette 7, the gas concentration released from the surface of the resist-based wafer 8 has been found to be a low-concentration result.

From this consequence, by using the cooling unit 3 and the cooling station 6, and cooling the temperature of the wafer 8 in the step-by-step manner, it becomes possible to suppress the released gas from the surface of the wafer 8 and the organic degas released from the cassettes 7.

Next, the confirmation has been carried out concerning the adhesion of the 50-nm-or-less microscopic foreign matters onto the before-ashing-processed wafer 8 inside the cassette 7. The foreign-matters evaluation method employed has been as follows: The resist-based wafers 8 for executing the ashing's continuous processing are set up at the 1st to 24th stages inside the same cassette 7. Moreover, a foreign-matters-measurement-dedicated silicon-based wafer 8 is set up at the 25th stage therein.

As is the case with the above-described gas-concentration comparison experiment, the confirmation has been carried out with respect to the following two cases as follows: A case where, using the resist-based wafers 8 set up at the 1st to 24th stages, the 60-second-time-interval electrical discharge with oxygen gas is carried out at the about 300-° C. ashing stage temperature in the ashing unit 1, and after that, the wafers 8 are cooled down to about 100° C. in the cooling unit 3, and are then stored into the cassette 7 with the temperature of about 100° C. maintained; and a case where the resist-based wafers 8 are cooled down to 30° C. or lower in the cooling station 6, and are then stored into the cassette 7. Then, the resist-based wafers 8 are left unprocessed inside the cassette 7 for a constant time-interval. After that, the confirmation is carried out regarding an increased number of the foreign matters adhering onto the foreign-matters-measurement-dedicated silicon-based wafer set up at the 25th stage.

As a consequence of the confirmation, in the case where no cooling is carried out in the cooling station 6, the increased number of the 50-nm-or-less foreign matters has been found to be 3782. This is a significantly large number. In contrast thereto, in the case where the cooling is carried out in the cooling station 6, the increased number of the 50-nm-or-less foreign matters has been found to be 1061. This means that the increased number of the foreign matters has been successfully reduced down to about the one-third.

From this consequence, by using the cooling unit 3 and the cooling station 6, and cooling the temperature of the wafer 8 in the step-by-step manner, it has become possible to reduce the adhesion of the foreign matters onto the wafer 8.

Incidentally, in the present embodiment, the processing in the vacuum containers has been explained in the case of the ashing processing. The present embodiment, however, is also effective in plasma etching, CVD, and high-temperature processings other than the above-described high-temperature processing. Accordingly, the present embodiment also makes it possible to provide basically the same effects in these technological fields.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing system, comprising:
a cassette holder for setting up cassettes in which a plurality of samples are stored;
an air transfer chamber for transferring said samples;
lock chambers for storing said samples transferred from said air transfer chamber, said lock chambers being capable of making a switching between air atmosphere and vacuum atmosphere in their inside;
a vacuum transfer chamber connected to said lock chambers;
vacuum containers for processing said samples transferred via said vacuum transfer chamber;
a cooling chamber for cooling said samples down to a first temperature, said samples being processed in at least one of said vacuum containers; and
a cooling unit for cooling said samples down to a second temperature, said samples being cooled in said cooling chamber, wherein
said cooling unit is deployed in said air transfer chamber, said cooling unit having a cooling part for cooling said samples down to said second temperature, said samples being cooled in said cooling chamber.

2. The vacuum processing system according to claim 1, wherein said first temperature is equal to about 100° C.

3. The vacuum processing system according to claim 1, wherein said first temperature is equal to about 100° C., said second temperature being equal to about 30° C. or lower.

4. The vacuum processing system according to claim 1, wherein said cooling part includes each stage for mounting each sample thereon and cooling each sample, each sample being held by each stage in a proximity-holding state.

5. The vacuum processing system according to claim 1, wherein said cooling part includes each stage for mounting each sample thereon and cooling each sample, the number of said stages being greater than or equal to the number of said vacuum containers.
